(19) United States
(12) Patent Application Publication
(10) Pub. No.: US 2005/0285612 A1
(43) Pub. Date: Dec. 29, 2005

(54) Apparatus for measuring DC parameters in a wafer burn-in system

(75) Inventor: Jang-wook Heo, Incheon (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: From Thirty Incorporated, Gyunggi-do (KR)

(21) Appl. No.: 10/875,121

(22) Filed: Jun. 23, 2004

(51) Int. Cl. G01R 31/26

(52) U.S. Cl. 324/765

(57) ABSTRACT

The present invention relates to an apparatus for measuring DC parameters which has a simplified hardware constitution of a DC block by simplifying the connection relationship of the DC block and DUTs for measuring DC parameters in a wafer burn-in system, and which can cause the processing time for measuring the DC parameters to be reduced by making it possible to receive more DUTs. According to the present invention, there is provided an apparatus for measuring DC parameters in a wafer burn-in system, comprising: n same circuits for measuring the DC parameters, wherein the n circuits are connected one-to-one to n switching means (DRy), and each of the n circuits is connected to eighteen (18) DUTs (Devices Under Test) through each of the n switching means (DRy). According to such a present invention, the constitution can be advantageously minimized in the hardware relatively compared with an apparatus for measuring DC parameters provided in the conventional wafer burn-in system. In addition, by increasing more than twice the number of the DUTs which can be treated by the single process, the time for measuring the DC parameters in the wafer burn-in process can be effectively reduced.

### BACKGROUND OF THE INVENTION

1. Field of Invention

The present invention relates to a wafer burn-in system, and more particularly, to an apparatus for measuring DC parameters for respective semiconductor devices on a wafer in a wafer burn-in system.

2. Description of the Prior Art

Generally, a wafer bum-in process is a kind of test process for determining whether semiconductor devices on a wafer are normal or abnormal by applying a higher voltage than conventional working voltage (5.0V) to the semiconductor devices at a high temperature (about 125° C.) that is a worse condition than a working condition of the semiconductor devices, before the semiconductor devices are supplied to final customers. The wafer burn-in process is generally performed in a post-process of a semiconductor manufacturing process. In addition, by performing such a wafer burn-in process, reliability and productivity of the semiconductor devices can be secured at an early stage.

In connection with this, FIG. 1 shows the general configuration of a conventional wafer bum-in system. The conventional wafer burn-in system comprises a computer 100, a wafer loading apparatus 200, a performance measuring board 250, and a main testing apparatus 300, each of which is generally constituted as an independent separate apparatus. That is, the wafer loading apparatus 200, the performance measuring board 250, and the main testing apparatus 300 shown in FIG. 1, each of which is constituted as an independent separate apparatus, are interconnected by predetermined connecting manners, and then, perform the wafer burn-in process.

Referring to FIG. 1, the functions of these components will be described. First, the computer 100 comprising a general personal computer or workstation controls the wafer burn-in process by providing execution conditions and commands for the wafer bum-in process, which are inputted by a user, to the main testing apparatus 300, which will be described below, and monitors progressive states of the process according thereto.

The wafer loading apparatus 200 functions to deliver the wafer to be tested to the performance measuring board 250, which will be described below, load and align the wafer, and unload the wafer after the test is completed.

The performance measuring board 250, which tests the wafer that is loaded by the wafer loading apparatus 200, comprises a plurality of measuring devices for performing the burn-in test, a plurality of pins for connecting to the wafer, a display (e.g., LED) for displaying the progressive states of the test, and the like. The performance measuring board 250 transmits various test signals including predetermined voltages according to the burn-in process on the basis of control signals provided from the main testing apparatus 300, which will be described below, to the wafer through a plurality of the pins. In addition, the performance measuring board 250 also transmits signals outputted from the wafer correspondingly to the test signals to the main testing apparatus 300.

The main testing apparatus 300 performs and controls the whole test process according to the wafer bum-in process on the basis of the execution commands inputted through the aforementioned computer 100. Connected to the aforementioned performance measuring board 250, the main testing apparatus 300 generates the various test signals including the predetermined voltage for performing the test, and then, provides them to the performance measuring board 250. In addition, combining output signals provided from performance measuring board 250 again, the main testing apparatus 300 provides test result signals according to the combined output signals to an alarm device, which is not shown but will be described below, or transmits them to its own monitor (not shown) or the computer 100. Therefore, the main testing apparatus 300 comprises various components for performing the wafer burn-in test, such as, for example, a plurality of timing clock generating means, test wave generating means, memory means for storing control commands for the execution, wave monitoring means, drivers, DC parameter measuring means, a CPU for analyzing detecting signals and operations of such components, and a display means (e.g., a monitor) for displaying the whole processing states.

In addition, such various components are mounted in the main testing apparatus 300 of the wafer burn-in system in the form of a plurality of boards having their corresponding functions, respectively, and generate the various test signals by mutually organic combination between the boards.

In the boards mounted in the main testing apparatus of the conventional wafer burn-in system as described above in connection with the present invention, a DC board for measuring DC parameters for the respective semiconductor devices on the wafer is included.

The DC board measures the DC parameters for the respective semiconductor devices on the wafer according to test modes. As the test modes of the DC board, there are a VSIM mode for measuring a current flowing in each semiconductor device responding to a predetermined voltage applied to the semiconductor device, an ISVM mode for measuring a voltage applied to each semiconductor device responding to a predetermined current applied to the semiconductor device, and a VM mode for measuring a voltage applied to each semiconductor device practically. In addition, the DC board is generally interconnected to a PD (Pulse Driver) board in the main testing apparatus 300, so that the DC board measures the DC parameters for the respective semiconductor devices on the wafer.

The DC board used in such a conventional wafer burn-in system includes eight (8) same DC circuits, each of which can measure the eight parameters. That is, the DC board consists of eight same blocks that are constituted by the same circuits, wherein each of the blocks can measure the DC parameters for eight DUTs (Devices Under Test). Therefore, the DC board can measure the DC parameters for the sixty four (64) semiconductor devices formed on the wafer.

FIG. 2 shows the exemplary connection relationship of the DC block and the DUTs included in the DC board in the conventional wafer bum-in system.

As shown in FIG. 2, the DC block 310 can measure the DC parameters for the eight DUTs, wherein the DC block 310 is connected to the DUTs through relay switches DRy1 to DRy8, respectively. That is, the DC block 310 can measure the DC parameters for the respective DUTs by turning on the respective relay switches DRy1 to DRy8. At this time, signals generated from the DC block are transmitted to the semiconductor devices on the wafer through PD blocks formed in a PD board of the main testing apparatus 300, respectively.

FIG. 3 is a view showing the connection relationship of the PD blocks in each of the DUTs shown in FIG. 2. Referring to the figure, the DUT includes twelve (12) PD blocks 321 to 332. In addition, the PD blocks 321 to 332 perform an on/off control for relay switches PRy1 and PRy1′ to PRy12 and PRy12′, respectively, so that the DC parameters are measured by the DC block 310 or PD parameters are measured by the PD blocks.

That is, when the PD parameters are measured in the respective PD blocks 321 to 332, by turning on the relay switches PRy1 to PRy12 connected to the PD blocks and turning off the relay switches PRy1′ to PRy12′ connected to the DC block 310, the PD parameters can be measured, respectively.

On the other hand, in the process for measuring the DC parameters for the respective semiconductor devices on the wafer by the DC block 310, the respective PD blocks 321 to 332 turn off the relay switches PRy1 to PRy12 and turn on the relay switches PRy1′ to PRy12′ connected to the DC block 310, respectively, so that the DC parameters are measured.

As a result, since the conventional DC board includes the eight DC blocks having the connection relationship shown in FIG. 2 and each of the DC blocks can measure the DC parameters for the eight DUTs, the DC parameters for the sixty-four DUTs can be simultaneously measured in the conventional wafer burn-in system.

In the meantime, in order that the main testing apparatus 300 can accommodate the two performance measuring boards 250 therein, the two DC boards are generally mounted in the main testing apparatus 300. Taking this into consideration, the DC parameters for the 128 semiconductor devices (i.e., two DC boards x eight blocks per DC board x eight semiconductor devices per block) can be measured through a single measuring process in the conventional wafer burn-in system.

As a result, when the DC parameters are measured by using the conventional wafer burn-in system which is constituted by the two stations each of which is mounted with two DC boards as described above, the DC parameters for the maximum 128 semiconductor devices can be measured through a measuring process.

However, since a practical wafer is formed with even more semiconductor devices than 128, considerable time is needed to measure the DC parameters for all semiconductor devices formed on the wafer. Particularly, since a diameter of a wafer has a tendency to increase lately, the number of the semiconductor devices formed on the wafer also increases. Therefore, measuring time of the DC parameters for a wafer also increases, which results in increase of the whole necessary time for performing the wafer burn-in process.

### SUMMARY OF THE INVENTION

Accordingly, the present invention is conceived to solve the aforementioned problems in the prior art. An object of the present invention is to provide an apparatus for measuring DC parameters which has a simplified hardware configuration of a DC block by simplifying the connection relationship of the DC block and DUTs for measuring DC parameters in a wafer burn-in system.

Another object of the present invention is to provide an apparatus for measuring DC parameters which can cause the processing time for measuring the DC parameters to be reduced by making it possible to receive more DUTs.

According to a preferred embodiment of the present invention for achieving the objects, there is provided an apparatus for measuring DC parameters for semiconductor devices in a wafer burn-in system, comprising: n same circuits for measuring the DC parameters, wherein the n circuits are connected one-to-one to n switching means DRy, and each of the n circuits is connected to eighteen DUTs (Devices Under Test) through each of the n switching means DRy.

### BRIEF DESCRIPTION OF THE DRAWINGS

The above and other objects, features and advantages of the present invention will become apparent from the following description of a preferred embodiment given in conjunction with the accompanying drawings, in which:

FIG. 1 is a view showing the whole configuration of a conventional wafer burn-in system;

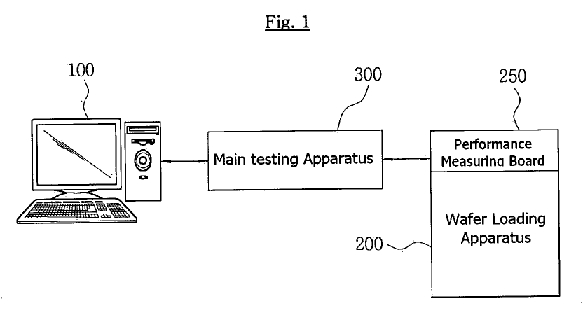

FIG. 2 is a view showing the connection relationship of a DC block and DUTs in a DC board in the conventional wafer burn-in system;

FIG. 3 is a view showing the connection relationship of PD blocks in each DUT shown in FIG. 2; and

FIG. 4 is a view showing the connection relationship of a DC block and DUTs according to an apparatus for measuring DC parameters of the present invention.

### DETAILED DESCRIPTION OF THE PREFERRED EMBODIMENT

Hereinafter, a preferred embodiment of the present invention will be described in detail with reference to the accompanying drawings.

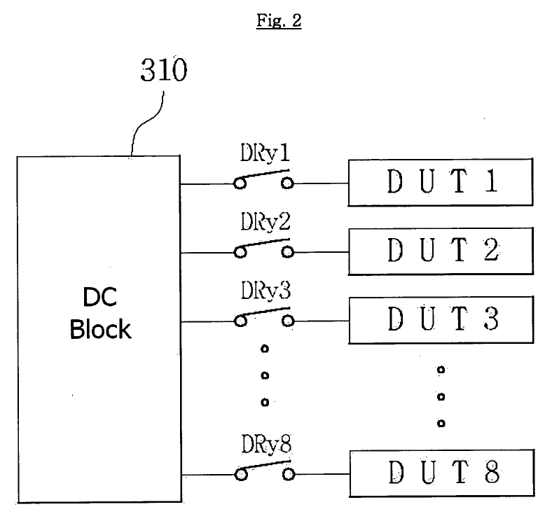

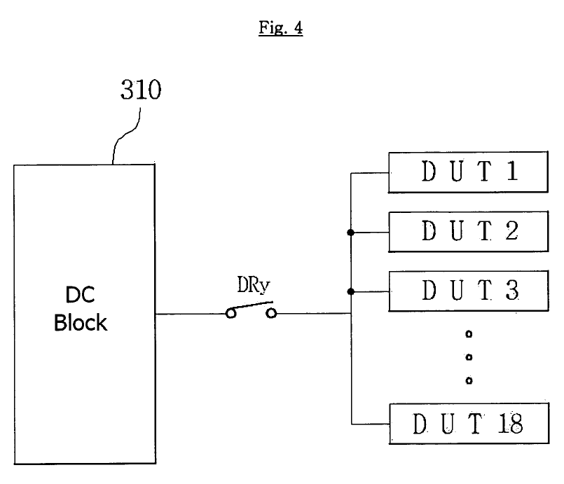

FIG. 4 is a view showing the connection relationship of a DC block and DUTs according to an apparatus for measuring DC parameters of the present invention. According to the present invention, each of the DC blocks formed in a DC board is constituted so that the DC block is connected to eighteen (18) DUTs DUT1 to DUT18 by using only a single relay switch DRy. That is, compared with the conventional the DC block shown in FIG. 2, the number of the relay switches connected to the DUTs is reduced from eight to one, and the number of the DUTs that the DC block 310 can receive is increased from eight to eighteen.

Therefore, when each of the DC blocks in the DC board is constituted as shown in FIG. 4, it is possible to measure the DC parameters for eighteen DUTs in each of the DC blocks. Thus, the DC parameters for all 144 DUTs can be measured in the single DC board including the eight DC blocks.

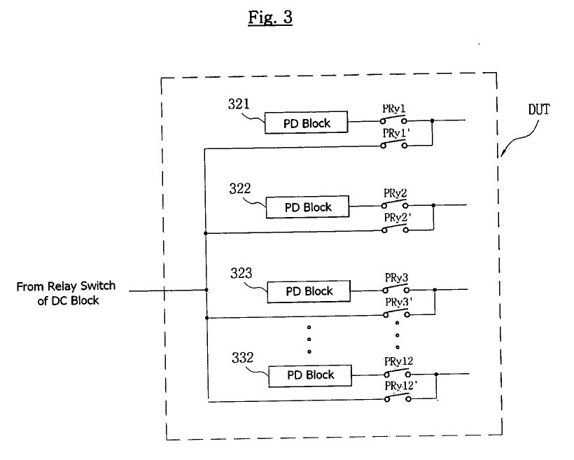

The connection relationship of the PD blocks in each of the eighteen DUTs DUTI to DUT18 shown in FIG. 4 is the same as in FIG. 3. Referring to FIGS. 3 and 4, an operation of the apparatus for measuring DC parameters according to the present invention will be described below.

First, in the process for measuring the DC parameters by the DC block 310, the relay switch DRy of the DC block 310 shown in FIG. 4 is turned on by a control of the DC block 310.

Then, the PD blocks 321 to 332 shown in FIG. 3 control an on/off operation of the relay switches PRy1 and PRy1′ to PRy12 and PRy12′ as before, respectively. That is, the PD blocks 321 to 332 turn off the relay switches PRy1 to PRy12 connected to the PD blocks and turn on the relay switches PRy1′ to PRy12′ connected to the DC block 310, respectively, so that it is possible that the DC block 310 measures the DC parameters by providing signals provided from the DC block 310 to semiconductor devices on a wafer through a performance measuring board 250.

Finally, since the present invention is provided with only the single relay switch for switching the connection between the DC block 310 and the DUTs, the DC board consisting of the eight DC blocks needs only the eight relay switches. Therefore, since the DC block is provided with the eight relay switches, the present invention can be relatively simplified in hardware compared with the conventional DC board which needs the minimum sixty-four relay switches

In addition, since the present invention is constituted so that the DC block 310 can receive the eighteen DUTs, the DC parameters for 144 DUTs can be simultaneously measured in the single DC board. Thus, the time for measuring the DC parameters can be reduced compared with the conventional DC board (including sixty-four DUTs), which makes it possible to effectively cope with a recent tendency to increase a diameter of a wafer.

According to the aforementioned present invention, the configuration of the hardware can be advantageously minimized as compared with an apparatus for measuring DC parameters provided in the conventional wafer burn-in system. In addition, by increasing more than twice the number of the DUTs which can be treated by the single measuring process, the time for measuring the DC parameters in the wafer burn-in process can be effectively reduced.

The aforementioned embodiments and the drawings only intend to explain the present invention, and do not intend to limit the scope of the present invention. Also, the present invention is not limited thereto but should be defined by the appended claims and their equivalents, since it will be apparent to those skilled in the art that various substitutions, modifications and changes may be made thereto without departing from the scope and spirit of the invention.

1. An apparatus for measuring DC parameters for semiconductor devices in a wafer bum-in system, comprising:
n same circuits for measuring the DC parameters,
wherein the n circuits are connected one-to-one to n switching means (DRy), and each of the n circuits is connected to eighteen DUTs (Devices Under Test) through each of the n switching means (DRy).

2. The apparatus as claimed in claim 1, wherein each of the DUTs is connected to m PD (Pulse Driver) blocks through a circuit which comprises m second switching means (PRy) and m third switching means (PRy′), the m second switching means (PRy) being connected one-to-one to the m PD blocks and controlled to be turned off in the process for measuring the DC parameters, the m third switching means (PRy′) being connected to the switching means (DRy) and controlled to be turned on in the process for measuring the DC parameters.
